(19) United States
(12) Patent Application Publication
(10) Pub. No.: US 2016/0241218 A1
(43) Pub. Date: Aug. 18, 2016

(54) SEMICONDUCTOR DEVICE

(71) Applicant: Renesas Electronics Corporation, Tokyo (JP)

(72) Inventors: Makoto MUNEYASU, Tokyo (JP); Takashi KONO, Tokyo (JP)

(73) Assignee: Renesas Electronics Corporation, Tokyo (JP)

(21) Appl. No.: 15/008,617

(22) Filed: Jan. 28, 2016

(30) Foreign Application Priority Data
Feb. 12, 2015 (JP) 2015-025114

(51) Int. Cl. H03K 3/013; H03K 5/135; H03K 4/06; H03K 5/24; H02M 3/07; H03K 3/03

(52) U.S. Cl. CPC H03K 3/013; H02M 3/07; H03K 3/0315; H03K 4/06; H03K 5/24; H03K 5/135

(57) ABSTRACT

In a semiconductor device, a charge pump operates in accordance with a clock signal and thereby generates a boosted voltage of a polarity which is the same as or reverse to the polarity of an input voltage. An oscillation circuit generates and outputs a clock signal. The oscillation circuit cyclically fluctuates a frequency of the clock signal within a predetermined fluctuation range. Thereby, EMI noise generated corresponding to the frequency of the clock signal for driving the charge pump is reduced.

### CROSS-REFERENCE TO RELATED APPLICATIONS

The disclosure of Japanese Patent Application No. 2015-025114 filed on Feb. 12, 2015 including the specification, drawings and abstract is incorporated herein by reference in its entirety.

### BACKGROUND

The present invention relates to a semiconductor device and is favorably utilizable in a semiconductor device which has, for example, a charge pump type booster circuit built-in.

As a circuit which generates a boosted voltage of a polarity which is the same as or reverse to the polarity of an input voltage, the charge pump type booster circuit is known. The charge pump type booster circuit which is disclosed, for example, in Japanese Unexamined Patent Application Publication No. 2004-129377 includes a so-called Dickson type charge pump, a pulse generation circuit and a comparator circuit.

In the booster circuit of this type, electrical charges are sequentially transferred among a plurality of capacitors provided in the charge pump in synchronization with a pulse signal which has been output from the pulse generation circuit. Consequently, a charging voltage of a capacitor located at a more rear stage than others is more raised than others and thereby a boosted voltage is obtained. The comparator circuit compares the boosted voltage which has been output from the charge pump with a reference voltage and performs on-off control on an output from the pulse generation circuit on the basis of a result of comparison.

Further, in the circuit disclosed in Japanese Unexamined Patent Application Publication No. 2004-129377, a predetermined number of pulses is output from the pulse generation circuit still after the boosted voltage has reached the reference voltage. The number of pulses generated at that time changes every time the output from the comparator circuit is switched.

### SUMMARY

The booster circuit disclosed in Japanese Unexamined Patent Application Publication No. 2004-129377 has an effect of reducing EMI (Electro Magnetic Interference) noise caused by an intermittent operation of the pulse generation circuit. However, no countermeasure is taken against the EMI noise generated corresponding to an operating frequency of the pulse generation circuit, that is, a frequency of a clock signal with which the charge pump is driven.

Other subject matters and novel features of the present invention will become apparent from description of the specification and the appended drawings of the present invention.

A semiconductor device according to one embodiment of the present invention has a charge pump built-in. The frequency of the clock signal with which the charge pump is driven is cyclically fluctuated within a predetermined fluctuation range.

In the semiconductor device according to the above-mentioned embodiment, it is possible to reduce the EMI noise generated corresponding to the frequency of the clock signal with which the charge pump is driven.

### BRIEF DESCRIPTION OF THE DRAWINGS

FIG. 1 is a block diagram illustrating one example of a configuration of a first charge pump type booster circuit 1.

FIG. 2 is a circuit diagram illustrating one example of a configuration of a charge pump 10 in FIG. 1.

FIG. 3 is a diagram illustrating one example of time variation of a frequency of a clock signal PUMPCLK.

FIG. 4 is a block diagram illustrating one configurational example of an oscillation circuit in FIG. 1.

FIG. 5 is a circuit diagram illustrating one example of a configuration of a voltage step-down converter 51 in FIG. 4.

FIG. 6 is a circuit diagram illustrating one example of a configuration of a triangular wave generator 60 in FIG. 4.

FIG. 7 is a timing chart illustrating one example of an operation of the triangular wave generator 60 in FIG. 6.

FIG. 8 is a block diagram illustrating another configurational example of the oscillation circuit in FIG. 1.

FIG. 9 is a circuit diagram illustrating a specific example of a configuration of a last-stage delay element LGn in FIG. 8.

FIG. 10 is a circuit diagram illustrating an altered example of the delay element LGn in FIG. 9.

FIG. 11 is a circuit diagram illustrating one example of a configuration of a second charge pump type booster circuit 2.

FIG. 12 is a diagram illustrating one example of waveforms of clock signals PUMP CLK1 and PUMPCLK2 output from an oscillation circuit 200 in FIG. 11.

FIG. 13 is a circuit diagram illustrating one example of a configuration of a charge pump type booster circuit 2A used in simulation.

FIG. 14 is a diagram illustrating one example of a spectrum that an FFT analysis was performed on consumption currents used for operating charge pumps 101 and 102 in FIG. 3.

FIG. 15 is a partially enlarged diagram of FIG. 14.

FIG. 16 is a block diagram illustrating a configurational example of a third charge pump type booster circuit 3.

FIG. 17 is a circuit diagram illustrating a more detailed configurational example of a variable delay unit 81 in FIG. 16.

FIG. 18 is a diagram illustrating one example of a waveform of a divided voltage of an output voltage from the charge pump 10 in FIG. 16.

FIG. 19 is a block diagram illustrating a configurational example of a fourth charge pump type booster circuit 4.

FIG. 20 is a circuit diagram illustrating a more detailed configurational example of a control circuit 30A in FIG. 19.

FIG. 21 is a diagram illustrating one example of a waveform of the divided voltage of the output voltage of the charge pump 10 in FIG. 19.

FIG. 22 is a circuit diagram illustrating an altered example 81A of the variable delay unit 81 in FIG. 17.

FIG. 23 is a block diagram illustrating one example of a configuration of a semiconductor device which has the charge pump type booster circuit built-in.

### DETAILED DESCRIPTION

In the following, preferred embodiments of the present invention will be described in detail with reference to the drawings. Incidentally, the same numerals are assigned to the same or corresponding parts and repetitive description thereof is omitted.

### First Embodiment

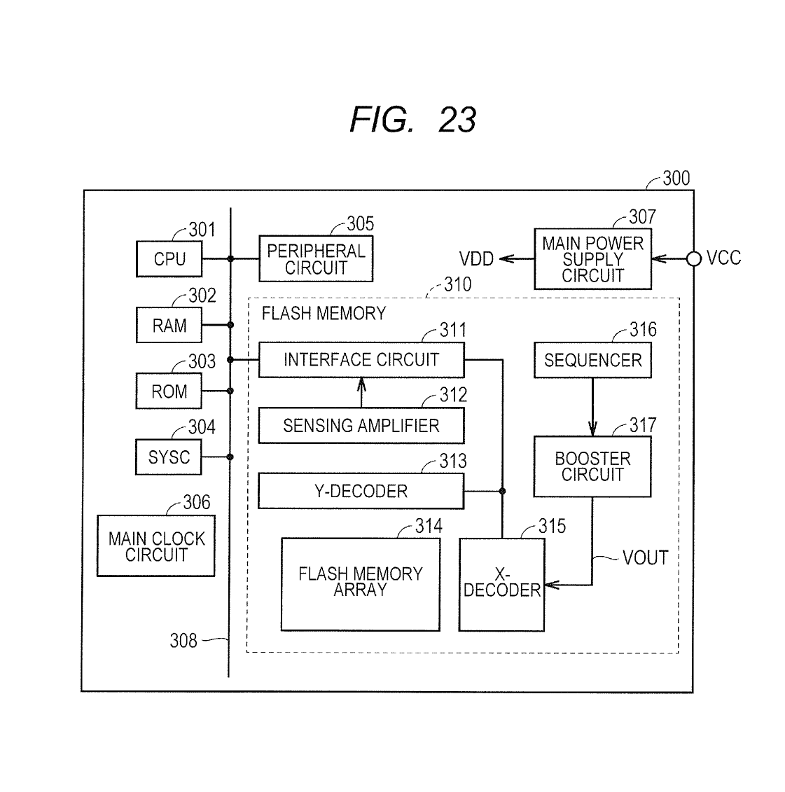

In the following, as the first embodiment, a first configurational example of a charge pump type booster circuit to be built in a semiconductor device will be described. Incidentally, one example of the semiconductor device which has the charge pump type booster circuit built-in will be described later with reference to FIG. 23.

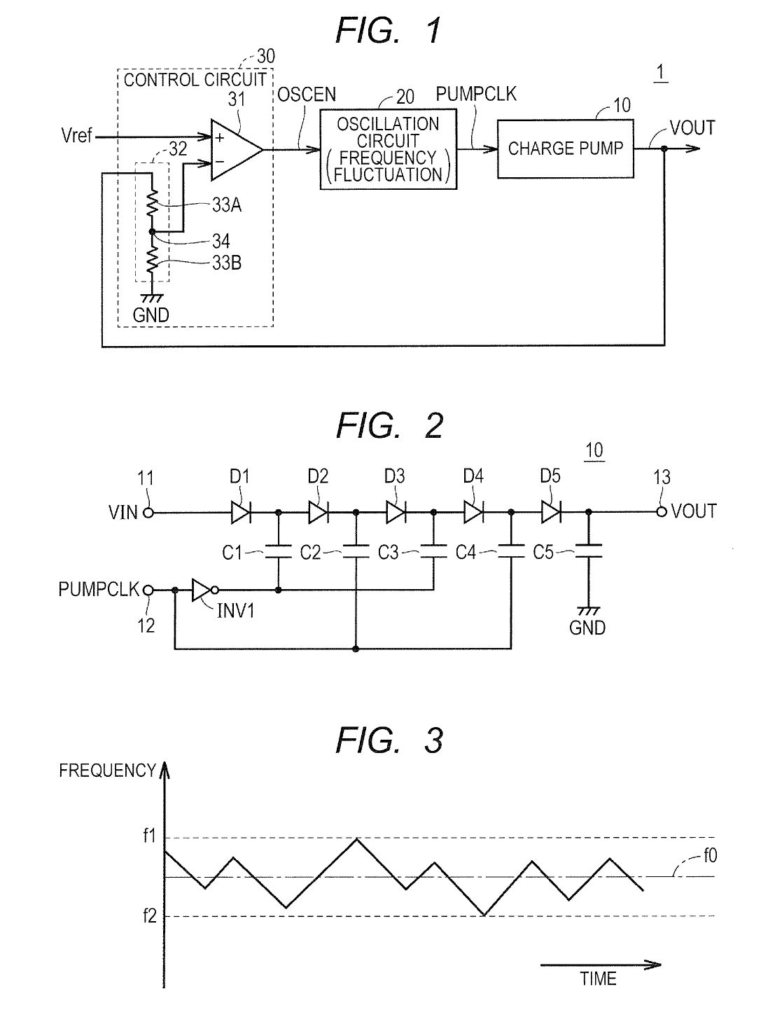

FIG. 1 is a block diagram illustrating one example of a configuration of the first charge pump type booster circuit 1. Referring to FIG. 1, the booster circuit 1 includes the charge pump 10, an oscillation circuit 20, a control circuit 30 and so forth.

The charge pump 10 operates in response to the clock signal PUMPCLK generated by the oscillation circuit 20 and thereby generates a boosted voltage of a polarity which is the same as or reverse to the polarity of an input voltage. When an input of the clock signal PUMPCLK is stopped, a boosting operation of the charge pump 10 is stopped.

FIG. 2 is a circuit diagram illustrating one example of a configuration of the charge pump 10 in FIG. 1. The charge pump 10 in FIG. 1 is a so-called Dickson type charge pump. In the following, the configuration and the operation of the charge pump 10 will be briefly described wither reference to FIG. 2. Incidentally, the configuration of the charge pump 10 used in the present embodiment is not limited to the configuration in FIG. 2.

Referring to FIG. 2, the charge pump 10 includes an input node 11, a signal node 12, an output node 13, a plurality of capacitors C1 to C5, a plurality of diodes D1 to D5, an inverter INV1 and so forth.

First, a configuration of the charge pump 10 will be described. An input voltage VIN is input into the input node 11. The clock signal PUMPCLK is input into the signal node 12. The diodes D1 to D5 are coupled in series with one another between the input node 11 and the output node 13 in a forward direction (that is, such that the input node 11 is located on the anode side and the output node 13 is located on the cathode side). The capacitors C1 to C5 respectively correspond to the diodes D1 to D5 and one end of each capacitor is coupled to a cathode of the corresponding diode. The other ends of the odd-numbered capacitors C1 and C3 other than the last-stage capacitor C5 are coupled with the signal node 12 via the inverter INV1. The other ends of the even-numbered capacitors C2 and C4 are directly coupled with the signal node 12. The other end of the last-stage capacitor C5 is coupled to a ground node (a ground voltage GND).

Next, an operation of the charge pump 10 will be described. When the clock signal PUMPCLK is at a high level (an H level), the odd-numbered diodes D1, D3 and D5 enter ON states and the even-numbered diodes D2 and D4 enter OFF states. Thereby, the electric charge is given from the input node 11 to the capacitor C1, the electric charge of the capacitor C2 is transferred to the capacitor C3 and the electric charge of the capacitor C4 is transferred to the capacitor C5. On the other hand, when the clock signal PUMPCLK is at a low level (an L level), the even-numbered diodes D2 and D4 enter the ON states and the odd-numbered diodes D1, D3 and D5 enter the OFF states. Thereby, the electric charge of the capacitor C1 is transferred to the capacitor C2 and the electric charge of the capacitor C3 is transferred to the capacitor C4. Owing to the above, the electric charges of the capacitors C1 to C5 are sequentially transferred in response to the clock signal PUMPCLK. Consequently, a charging voltage of a capacitor located at a more rear stage than others is made higher than others. Consequently, an output voltage VOUT which has been boosted with the same polarity as that of the input voltage VIN is charged to the capacitor C5.

As apparent from the above mentioned operations, the more the number of the capacitors coupled is increased, the higher the finally attainable voltage becomes. In addition, when the input voltage VIN (the input node 11) is coupled to the output node 13, the boosted voltage of the polarity which is reverse to the polarity of the input voltage VIN is obtained at the input node 11.

Again, referring to FIG. 1, the oscillation circuit 20 generates the clock signal PUMPCLK to be supplied to the charge pump 10. Here, the present embodiment has a feature in the point that the oscillation circuit 20 cyclically fluctuates the frequency of the clock signal PUMPCLK that the oscillation circuit 20 itself generates within a predetermined fluctuation range.

FIG. 3 is a diagram illustrating one example of time variation of the frequency of the clock signal PUMPCLK. Referring to FIG. 3, although the frequency of the clock signal PUMPCLK to be generated by the oscillation circuit 20 exhibits a frequency designated by f0 averagely, it is cyclically changed within a range from an upper limit frequency f1 to a lower limit frequency f2. As illustrated in FIG. 3, it is not necessary to set a cycle of frequency fluctuation constant. likewise, it is not necessary to set a band of fluctuation constant per cycle. It goes without saying that the frequency may be fluctuated in a constant cycle and with constant amplitude. Further, although the frequency is continuously changed in the example in FIG. 3, the frequency may be changed discretely, that is, the plurality of frequencies may be prepared so as to switch from one frequency to another frequency. It is possible to reduce the EMI noise generated corresponding to the operating frequency of the oscillation circuit 20 by giving fluctuations to the clock signal PUMPCLK in this way.

Again, referring to FIG. 1, the control circuit 30 is provided in order to perform on-off control on an output from the oscillation circuit 20 and thereby control the output voltage VOUT of the charge pump 10 to a predetermined level. Specifically, the control circuit 30 includes a voltage division circuit 32 which divides the output voltage VOUT of the charge pump 10, a comparator 31 and so forth.

The voltage division circuit 32 is, for example, a resistive voltage division circuit which divides the output voltage VOUT of the charge pump 10 by series-coupled resistance elements 33A and 33B. The comparator 31 compares a voltage (a divided voltage) of a coupling node 34 of the resistance elements 33A and 33B with a reference voltage Vref. The comparator 31 outputs an enable signal OSCEN to the oscillation circuit 20 as a control signal on the basis of a result of comparison.

The enable signal OSCEN is activated when the reference voltage Vref has exceeded the divided voltage of the output voltage VOUT. The oscillation circuit 20 is configured to perform an oscillating operation when the enable signal OSCEN is in an active state and to stop the oscillating operation when the enable signal OSCEN is in an inactive state. The oscillation circuit 20 stops the oscillating operation, that is, inputting of the clock signal PUMPCLK into the charge pump 10 is stopped and thereby the charge pump 10 stops a boosting operation. Thereby, it is possible to adjust the output voltage VOUT of the charge pump 10 to a constant level.

As described above, according to the first embodiment, it is possible to reduce the EMI noise generated in an operating frequency band of the oscillation circuit 20 by cyclically changing the frequency of the clock signal PUMPCLK output from the oscillation circuit 20 within the predetermined fluctuation range.

### Second Embodiment

In the second embodiment, more detailed configurational examples of the oscillation circuit 20 in FIG. 1 will be described. In the following examples, each of oscillation circuits 20A and 20B is configured by a ring oscillator. Then, a delay time of at least one of delay elements which configure the ring oscillator is cyclically fluctuated within the predetermined fluctuation range. Thereby, it is possible to cyclically fluctuate an oscillating frequency of the oscillation circuit 20 within the predetermined fluctuation range. In the following, the second embodiment will be specifically described with reference to the drawings.

[First Configurational Example of Oscillation Circuit]

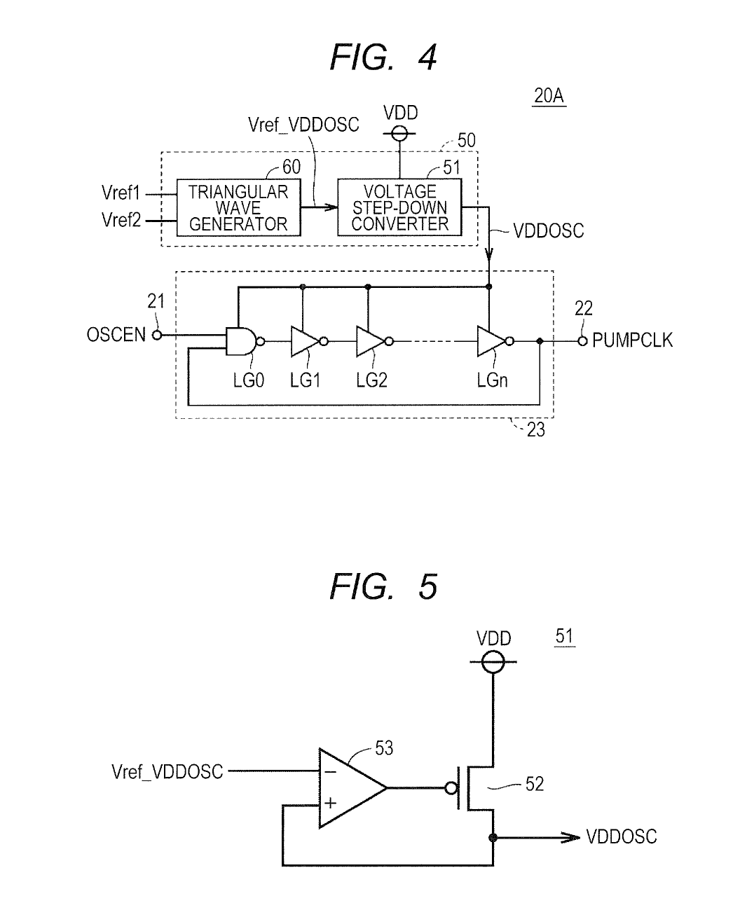

FIG. 4 is a block diagram illustrating one example of a configuration of the oscillation circuit 20 in FIG. 1. Referring to FIG. 4, the oscillation circuit 20A according to the first configurational example includes a ring oscillator 23, a power supply circuit 50 and so forth.

The ring oscillator 23 is configured by combining together the plurality of delay elements in a ring-shape. In the example in FIG. 4, each of the delay elements is configured by a logic gate which reverses a pulse signal that a preceding-stage delay element outputs and outputs the pulse signal so reversed to the next-stage delay element. Specifically, a first-stage delay element LG0 is configured by a NAND gate and each of n (n is an even number) delay elements LG1 to GLn ranging from the next-stage delay element to the last-stage delay element is configured by an inverter. An output from the last-stage delay element LGn is supplied to the charge pump 10 as the clock signal PUMPCLK and is again input into the first-stage delay element LG0 (the NAND gate). In addition, the enable signal OSCEN is input into the first-stage delay element LG0 (the NAND gate) from the control circuit 30. Since when the enable signal OSCEN is in the inactive state (the L level), the output from the delay element LG0 (the NAND gate) is fixed to the H level, the oscillating operation of the ring oscillator 23 is stopped.

The power supply circuit 50 supplies the operating voltage to at least one of the plurality of logic gates LG0 to LGn (in the example in FIG. 4, the operating voltage is supplied from the power supply circuit 50 to all of the logic gates LG0 to LGn). The power supply circuit 50 cyclically fluctuates the operating voltage to be output within the predetermined fluctuation range. Thereby, it is possible to cyclically fluctuate the delay time of the logic gate which operates at this operating voltage within the predetermined fluctuation range.

Describing in more detail, the power supply circuit 50 includes the triangular wave generator 60, the voltage step-down converter 51 and so forth. The triangular wave generator 60 generates a triangular wave of a voltage which is cyclically fluctuated between a first voltage and a second voltage. The voltage step-down converter 51 drops a power supply voltage VDD which has been applied thereto in accordance with a voltage level Vref_VDDOSC of the triangular wave and thereby generates an operating voltage VDDOSC to be supplied to the logic gates LG0 to LGn.

FIG. 5 is a circuit diagram illustrating one example of a configuration of the voltage step-down converter 51 in FIG. 4. Referring to FIG. 5, the voltage step-down converter 51 includes a PMOS (P-channel Metal Oxide Semiconductor) transistor 52, a differential amplifier 53 and so forth.

A source of the PMOS transistor 52 is coupled to the power supply node (the power supply voltage VDD) and a drain of the PMOS transistor 52 is coupled to a plus terminal of the differential amplifier 53. The output voltage Vref_VDDOSC of the triangular wave generator 60 is input into a minus terminal of the differential amplifier 53.

According to the above-mentioned configuration, a drain voltage of the PMOS transistor 52 is subjected to feedback control so as to be equal to the output voltage Vref_VDDOSC of the triangular wave generator 60. The drain voltage is supplied to the logic gates LG0 to LGn as the operating voltage VDDOSC.

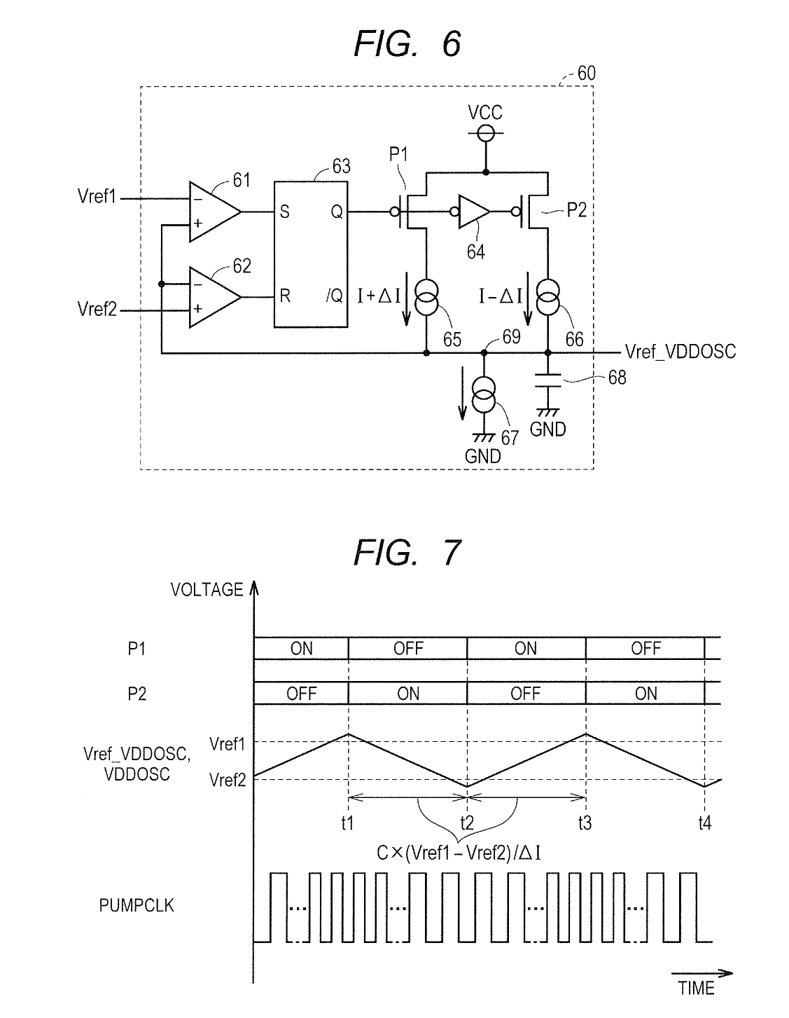

FIG. 6 is a circuit diagram illustrating one example of a configuration of the triangular wave generator 60 in FIG. 4. Referring to FIG. 6, the triangular wave generator 60 includes comparators 61 and 62, an SR flip-flop 63, PMOS transistors P1 and P2, an inverter 64, constant current sources 65 to 67, a capacitor 68 and so forth. The constant current source 65 flows out a constant current I+ΔI, the constant current source 66 flows out a constant current I−ΔI, and the constant current source 67 flows out a constant current I.

The PMOS transistor P1 and the constant current source 65 are series-coupled between the power supply node to which an external power supply voltage VCC is to be applied and an intermediate node 69. Likewise, the PMOS transistor P2 and the constant current source 66 are series-coupled between the power supply node (the external power supply voltage VCC) and the intermediate node 69 and are coupled in parallel with the entire of the PMOS transistor P1 and the constant current source 65. The constant current source 67 and the capacitor 68 are parallel-coupled between the intermediate node 69 and a ground node (a ground voltage GND). The intermediate node 69 is further coupled to a plus terminal of the comparator 61 and a minus terminal of the comparator 62. A reference voltage Vref1 is input into the minus terminal of the comparator 61 and a reference voltage Vref2 is input into the plus terminal of the comparator 62. An output of the comparator 61 is input into a set terminal S of the SR flip-flop 63 and an output of the comparator 62 is input into a reset terminal R of the SR flip-flop 63. An output terminal Q of the SR flip-flop 63 is coupled to a gate of the PMOS transistor P1 and is coupled to a gate of the PMOS transistor P2 via the inverter 64.

FIG. 7 is a timing chart illustrating one example of the operation of the triangular wave generator 60 in FIG. 6. In the example in FIG. 7, the ON and OFF states of the PMOS transistors P1 and P2 and waveforms of the voltage Vref_VDDDOSC of the intermediate node 69 (equal to the operating voltage VDDOSC to be supplied to the logic gates LG0 to LGn) and the clock signal PUMPCLK are illustrated in order from the top. In the following, the operation of the triangular wave generator 60 will be described with reference to FIG. 6 and FIG. 7.

When the voltage Vref_VDDOSC of the intermediate node 69 is at a level between the reference voltages Vref1 and Vref2, outputs from the comparators 61 and 62 are reduced to the L level. In this case, if the flip-flop 63 is in a reset state, the PMOS transistor P1 will be turned on (ON) and the PMOS transistor P2 will be turned off (OFF). Consequently, the current flowing into the capacitor 68 is increased to ΔI and therefore the voltage Vref_VDDOSC of the intermediate node 69 rises.

When the voltage Vref_VDDOSC of the intermediate node 69 exceeds the reference voltage Vref1 at a time t1 (also at a time 3), the output from the comparator 61 is increased to the H level (the comparator 62 is still at the L level). Therefore, the flip-flop 63 is switched to the set state. Consequently, the PMNOS transistor P1 is turned off and the PMOS transistor P2 is turned on. In this case, since the current flowing into the capacitor 68 is reduced to −ΔI, the voltage Vref_VDDOSC of the intermediate node 69 drops.

When the voltage Vref_VDDOSC of the intermediate node 69 becomes lower than the reference voltage Vref at a time t2 (also at a time t4), the output from the comparator 62 is increased to the H level (the comparator 61 is still at the L level). Therefore, the flip-flop 63 is switched to the reset state. Consequently, the PMNOS transistor P1 is turned on and the PMOS transistor P2 is turned off. In this case, since the current flowing into the capacitor 68 is increased to ΔI, the voltage Vref_VDDOSC of the intermediate node 69 rises.

The voltage Vref_VDDOSC of the intermediate node 69 turns to a triangular wave voltage which is continuously changed between the reference voltages Vref1 and Vref2 by repeating the above-mentioned operations. The operating voltage VDDOSC which is to be supplied to the logic gates LG0 to LGn works together with the voltage Vref_VDDOSC of the intermediate node 69. Accordingly, it is possible to output the clock signal PUMPCLK the cycle of which is cyclically and continuously fluctuated as illustrated in FIG. 7 from the oscillation circuit 20A which operates at the operating voltage VDDOSC.

Incidentally, supposing that C denotes a capacitance of the capacitor 68, the magnitude of the voltage which is reduced per unit time between the time t1 and the time t2 in FIG. 7 will be given by ΔI/C. Likewise, the magnitude of the voltage which is increased per unit time between the time t2 and the time t3 will be given by ΔI/C. Accordingly, a length of the term between the time t1 and the time t2 (also the term between the time t2 and the time t3) will be given by C×(Vref1−Vref2)/ΔI.

[Second Configurational Example of Oscillation Circuit]

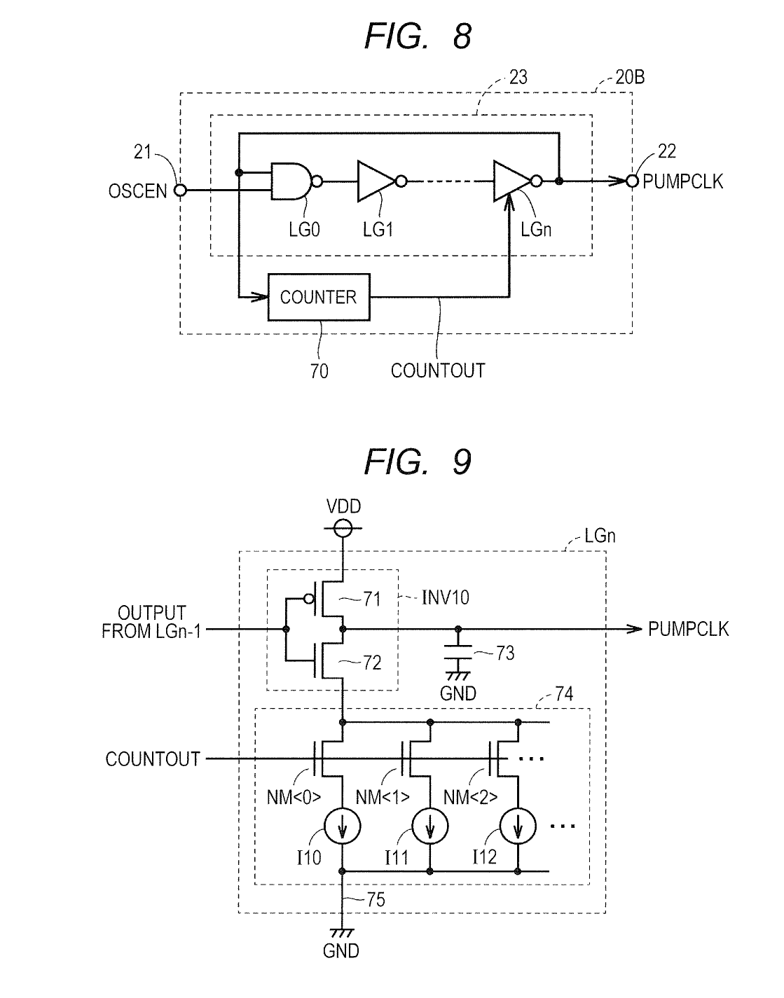

FIG. 8 is a block diagram illustrating another configurational example of the oscillation circuit in FIG. 1. Referring to FIG. 8, the oscillation circuit 20B according to the second configuration example includes the ring oscillator 23, a counter 70 and so forth. The counter 70 counts the number of pulses of the clock signal PUMPCLK to be output from the ring oscillator 23. It is supposed that the number of counts of the counter 70 is cyclically reset. Incidentally, when the number of pulses of the clock signal PUMPCLK is counted by the counter 70, output pulses from any of the delay elements LF0 to LGn may be counted.

Although the configuration of the ring oscillator 23 is similar to that in FIG. 4, it is different from that of the ring oscillator 23 in FIG. 4 in the point that it is possible to change the delay amounts of at least some delay elements in accordance with the number of counts of the counter 70 (in the example in FIG. 8, the delay amount of the last-stage delay element LGn is made changeable). Thereby, it is possible to cyclically fluctuate the frequency of the clock signal PUMPCLK to be output from the oscillation circuit 20B within the predetermined fluctuation range and consequently it is possible to reduce the EMI noise generated corresponding to the operating frequency of the oscillation circuit 20B.

FIG. 9 is a circuit diagram illustrating a specific example of a configuration of the last-stage delay element LGn in FIG. 8. Referring to FIG. 9, the delay element LGn includes a CMOS (Complementary MOS) inverter INV10, a current source circuit 74 which makes it possible to change a current amount in accordance with an output COUNTOUT (the number of counts) of the counter 70, a capacitor 73 and so forth.

The CMOS inverter INV10 includes a PMOS transistor 71 and an NMOS (N-channel MOS) transistor 72 which are coupled in series with each other. The capacitor 73 may be coupled either between an output node of the CMOS inverter INV10 (a coupling node between the transistors 71 and 72) and the ground node (the ground voltage GND) as illustrated in FIG. 9 or between the output node of the CMOS inverter INV10 and the power supply node (the power supply voltage VDD) conversely.

A current source circuit 74 is inserted into a grounding wire 75 of the CMOS inverter INV10. That is, the current source circuit 74 is coupled between a source of the NMOS transistor 72 and the ground node (the ground voltage GND). The current source circuit 74 includes constant current sources 110, 111, 112 and so forth which are coupled in parallel with one another and NMOS transistors NM<0>, NM<1>, NM<2> and so forth respectively corresponding to the constant current sources 110, 111, 112 and so forth. Each of the NMOS transistors is coupled in series with the corresponding constant current source and is switched on or off in accordance with an output COUNTOUT of the counter 70. The current source circuit 74 is configured such that, for example, when the number of counts of the counter 70 is “0”, only the transistor NM<0> is turned on and when the number of counts of the counter 70 is “i”, i+1 NMOS transistors NM<0> to NM<i> are turned on.

According to the above-mentioned configuration, it is possible to change the delay amount obtained when the output from the CMOS inverter INV10 is switched from the H level to the L level in accordance with the number of counts of the counter 70. Specifically, the delay amount is reduced as the number of counts of the counter 70 is increased.

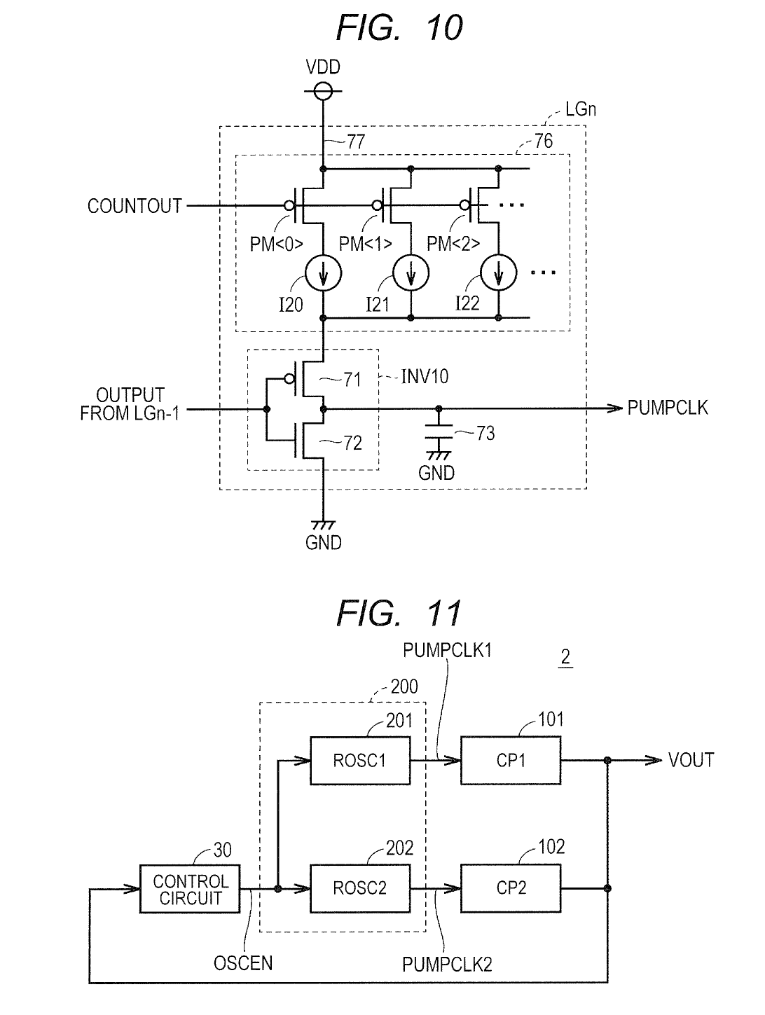

FIG. 10 is a circuit diagram illustrating an altered example of the delay element LGn in FIG. 9. As illustrated in FIG. 10, a current source circuit 76 may be provided in a power supply wire 77 of the CMOS inverter INV10, in place of the current source circuit 74 in FIG. 9. That is, the current source circuit 76 may be coupled between a source of the PMOS transistor 71 and the power supply node (the power supply voltage VDD).

The current source circuit 76 has a configuration similar to that of the current source circuit 74 in FIG. 9 and includes constant current sources 120, 121, 122 and so forth which are coupled in parallel with one another and PMOS transistors PM<0>, PM<1>, PM<2> and so forth respectively corresponding to the constant current sources 120, 121, 122 and so forth. Each of the PMOS transistors is coupled in series with the corresponding constant current source and is switched on or off in accordance with the output COUNTOUT of the counter 70. The current source circuit 76 is configured such that, for example, when the number of counts of the counter 70 is “0”, only the PMOS transistor PM<0> is turned on and when the number of counts of the counter 70 is “i”, i+1 PMOS transistors PM<0> to PM<i> are turned on. Also according to this configuration, it is possible to change the delay amount obtained when the output from the CMOS inverter INV10 is switched from the L level to the H level in accordance with the number of counts of the counter 70.

Moreover, it is also possible to provide the current source circuits 74 and 76 the current amount of each of which is made changeable in accordance with the output COUNTOUT (the number of counts) of the counter 70 in both of the grounding wire 75 and the power supply wire 77 of the CMOS inverter INV10. In this case, it is possible to change the delay amount at both of a timing at which the output from the CMOS inverter INV10 is switched from the L level to the H level and a timing at which the output from the CMOS inverter INV10 is switched from the H level to the L level in accordance with the number of counts of the counter 70. For example, supposing that d is the delay amount of each of the logic gates LG0 to LGn in FIG. 8 and the delay amount of the last-stage logic gate LGn has been changed by Δd, the cycle of the clock signal PUMPCLK will be expressed as (2×(n+1)×d+2×Δd). That is, it is possible to change the cycle of the clock signal PUMPCLK by 2×Δd.

### Advantageous Effects

According to the above-mentioned second embodiment, each of the oscillation circuit 20A and 20B adapted to generate the clock signal PUMPCLK for driving the charge pump 10 is configured by the ring oscillator 23. It becomes possible to cyclically fluctuate (give fluctuations to) the frequency of the clock signal PUMPCLK within the predetermined fluctuation range by cyclically fluctuating the delay amount of at least one of the delay elements which configure the ring oscillator 23 within the predetermined fluctuation range. Consequently, it is possible to reduce the EMI noise generated corresponding to the operating frequency of the oscillation circuit 20A.

### Third Embodiment

In the third embodiment, a second configurational example of the charge pump type booster circuit to be built in the semiconductor device will be described. The booster circuit is configured such that the plurality of charge pumps are coupled in parallel with one another, the operating frequency of the oscillation circuit for driving each charge pump is cyclically fluctuated within the predetermined fluctuation range and the operating frequencies of the respective charge pumps are made different from one another at the same hour. Thereby, it is possible to further reduce the EMI noise generated corresponding to the operating frequency of the oscillation circuit 20A.

[Configuration of Booster Circuit]

FIG. 11 is a circuit diagram illustrating one example of a configuration of the second charge pump type booster circuit 2. Referring to FIG. 11, the charge pump type booster circuit 2 includes the charge pumps 101 and 102 (CP1 and CP2), the oscillation circuit 200, the control circuit 30 and so forth.

The configuration of each of the charge pumps 101 and 102 is the same as the configuration of the charge pump 10 described with reference to FIG. 1 and FIG. 2. The oscillation circuit 200 generates the clock signal PUMPCLK1 for driving the charge pump 101 and the clock signal PUMPCLK2 for driving the charge pump 102. The control circuit 30 is configured in the same manner as that described with reference to FIG. 1 and generates the enable signal OSCEN as the control signal for performing on-off control on the output from the oscillation circuit 200 on the basis of the output voltage VOUT of each of the charge pumps 101 and 102.

In case of the example in FIG. 11, the oscillation circuit 200 includes a first oscillation circuit 201 (ROSC1) which generates the clock signal PUMPCLK1 and a second oscillation circuit 202 (ROSC2) which generates the clock signal PUMPCLK2. The configuration of each of the oscillation circuit 201 and 202 is the same as, for example, the configuration of each of the oscillation circuits 20A and 20B described with reference to FIG. 4 to FIG. 10 and each of the oscillation circuits 201 and 202 is configured by the ring oscillator. As described with reference to FIG. 4 to FIG. 10, it is possible to reduce the EMI noise generated corresponding to oscillation frequencies of the clock signals PUMPCLK1 and PUMPCLK2 by cyclically fluctuating the delay amount of at least one of the delay elements which configure the ring oscillator within the predetermined fluctuation range.

In order to more reduce the EMI noise, the frequency of the clock signal PUMPCLK1 and the frequency of the clock signal PUMPCLK2 obtained at the same hour are made different from each other. It is possible to make the oscillation frequencies different from each other by making, for example, the numbers of delay elements respectively configuring the oscillation circuits 201 and 202 different from each other. Alternatively, when the oscillation circuits 201 and 202 of the same configuration have been used, timings at which the respective frequencies are increase/decreased are made different from each other (in other words, phases of frequency fluctuations are made different from each other).

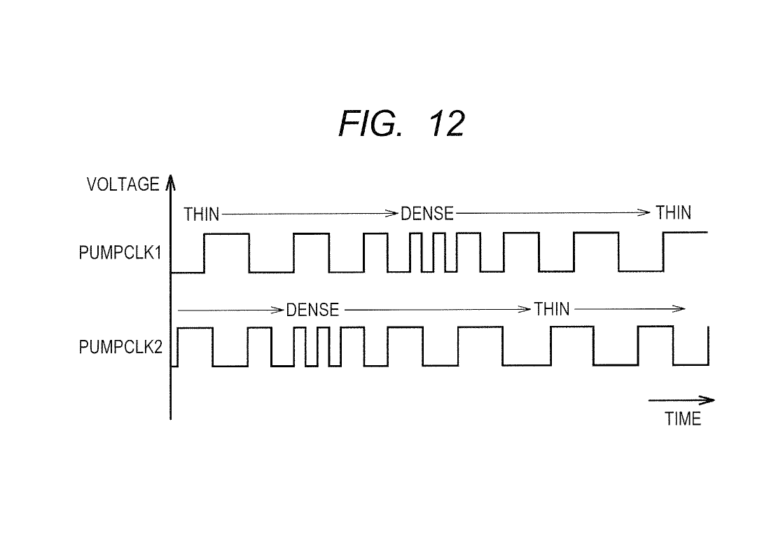

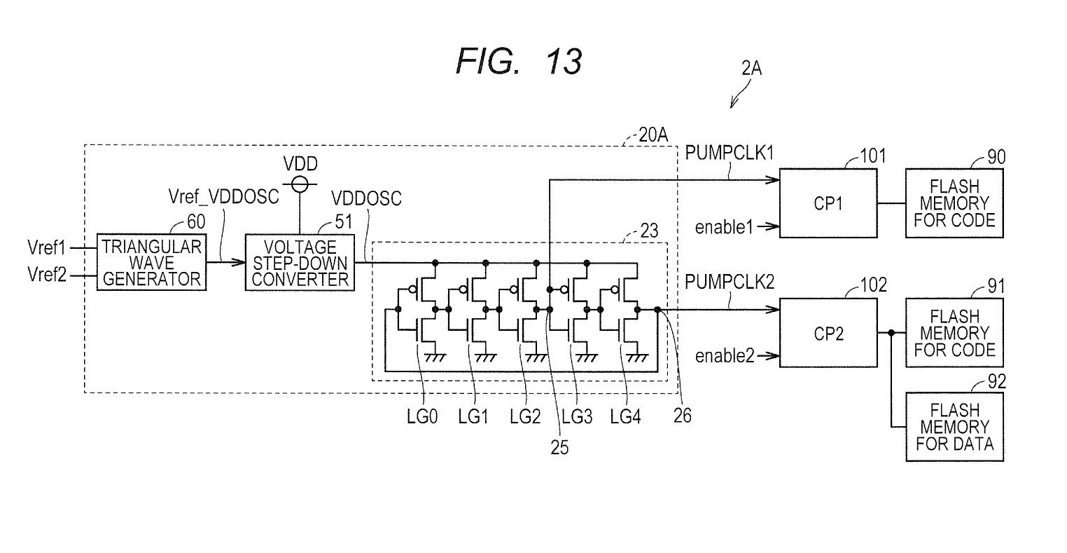

FIG. 12 is a diagram illustrating one example of waveforms of the clock signals PUMPCLK1 and PUMPCLK2 output from the oscillation circuit 200 in FIG. 11. In the example in FIG. 12, although the fluctuation cycle of the frequency of the clock signal PUMPCLK1 and the fluctuation cycle of the clock signal PUMPCLK2 are the same as each other, timings at which these frequencies are fluctuated deviate from each other by 1/4 of the fluctuation cycle (that is, the frequency fluctuations of these clock signals are about 90 degrees out-of-phase).

[Operational Example of Booster Circuit]

In the following, an EMI noise reduction effect attained by the present embodiment will be described on the basis of a result of simulation.

FIG. 13 is a circuit diagram illustrating one example of a configuration of the charge pump type booster circuit 2A used in the simulation. Referring to FIG. 13, the booster circuit 2A includes the charge pumps 101 and 102 (CP1 and CP2), the oscillation circuit 20A and so forth. The control circuit 30 included therein is not illustrated. The charge pump 101 supplies the boosted voltage to a flash memory for code 90, and the charge pump 102 supplies the boosted voltage to a flash memory for code 91 and a flash memory for data 92.

The oscillation circuit 20A is configured in the same manner as that described with reference to FIG. 4 to FIG. 6. That is, the oscillation circuit 20A includes the ring oscillator 23, the voltage step-down converter 51, the triangular wave generator 60 and so forth.

The ring oscillator 23 includes five COMS inverters LG0 to LG4 as the delay elements. An output from the CMOS inverter LG2 is supplied to the charge pump 101 as the clock signal PUMPCLK1 and an output from the CMOS inverter LG4 is supplied to the charge pump 102 as the clock signal PUMPCLK2. The clock signals PUMPCLK1 and PUMPCLK2 are taken out of the mutually different delay elements in the plurality of delay elements which configure the ring oscillator 23 in this way. Consequently, the clock signals PUMPCLK1 and PUMPCLK2 come to be about 72 degrees out-of-phase.

Moreover, as described with reference to FIG. 4 to FIG. 6, since the operating voltage to be supplied to each of the CMOS inverters LG0 to LG4 is cyclically fluctuated within the predetermined fluctuation range, fluctuations are generated in the frequencies of the clock signals PUMPCLK1 and PUMPCLK2.

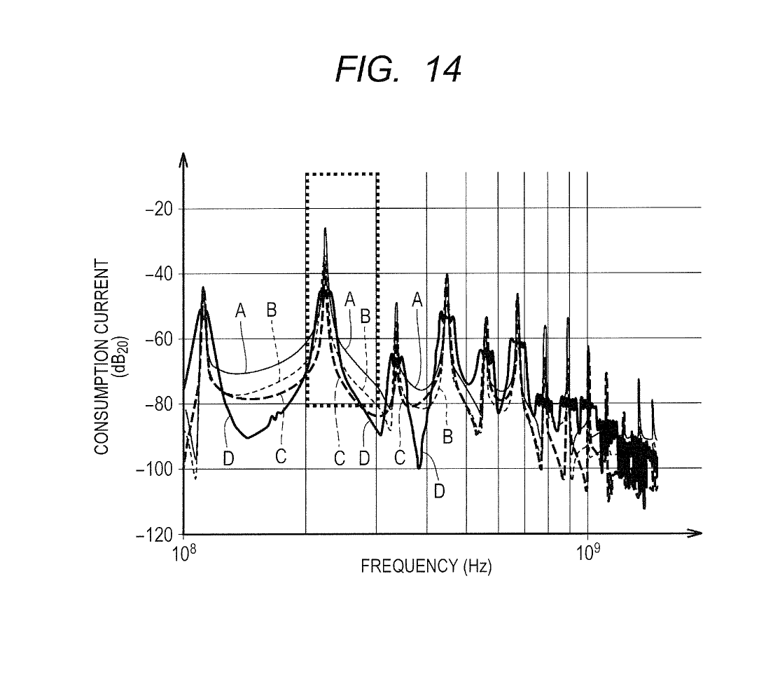

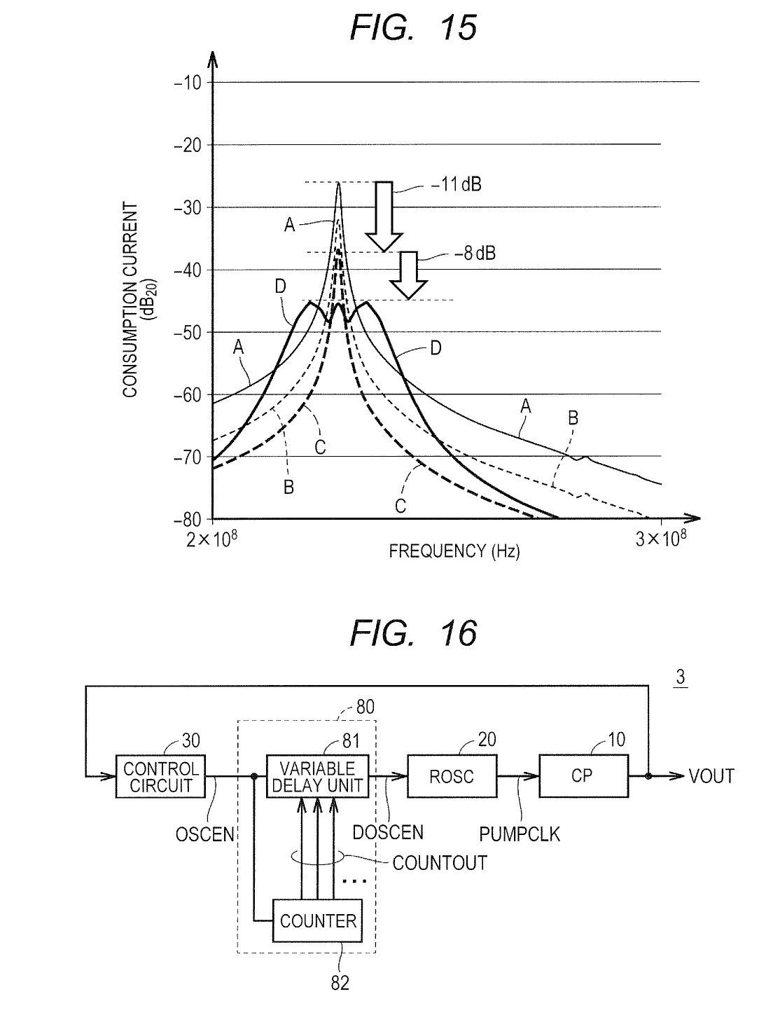

FIG. 14 is a diagram illustrating one example of a spectrum that an FFT (Fast Fourier Transform) analysis has been performed on consumption currents used by operations of the charge pumps 101 and 102 in FIG. 13. FIG. 15 is a partially enlarged diagram of FIG. 14. In FIG. 15, the spectrum (a broken-lined rectangular part) of the frequencies ranging from about 200 MHz to about 300 MHz in FIG. 14 is enlargedly illustrated.

In FIG. 14 and FIG. 15, a graph A (a comparative example) illustrates a case where the operating voltage VDDOSC was set constant with no fluctuation and both of the charge pumps 101 and 102 were driven with only the clock signal PUMPCLK1. A graph B (a comparative example) illustrates a case where the operating voltage VDDOSC was set constant with no fluctuation and only the charge pump 101 was driven with only the clock signal PUMPCLK1. A graph C (a comparative example) illustrates a case where although the operating voltage VDDOSC was set constant with no fluctuation, the mutually phase-shifted clock signals PUMPCLK1 and PUMPCLK2 were output. A graph D illustrates the case of the present embodiment.

As illustrated in FIG. 14 and FIG. 15, comparison of the graph A with the graph C verified that it is possible to reduce a noise peak by about 11 dB by driving the mutually different charge pumps by using the two phase-shifted clock signals. Comparison of the graph C with the graph D verified that it is possible to further reduce the noise peak by about 8 dB by giving fluctuations to the frequency of each clock signal.

### Advantageous Effects

As described above, it becomes possible to further reduce the EMI noise generated corresponding to the operating frequency of the oscillation circuit by providing the plurality of charge pumps and then mutually shifting the phases of the clock signals to be supplied to the respective charge pumps, and by giving fluctuations to the frequency of each clock signal. Incidentally, it is desirable to optimize a shift amount of the phase of each clock signal and the magnitude of frequency fluctuations by analyzing the noise of the entire booster circuit or the entire of a system including a load circuit of the booster circuit.

### Fourth Embodiment

In the fourth embodiment, a third configurational example of the charge pump type booster circuit to be built in the semiconductor device will be described. The fourth embodiment aims to reduce the EMI noise generated corresponding to the frequency of the intermittent operation when performing on-off control on the output from the oscillation circuit. It is possible to combine the fourth embodiment with any of the first to third embodiments.

FIG. 16 is a block diagram illustrating one configurational example of the third charge pump type booster circuit 3. The booster circuit 3 in FIG. 16 is different from the booster circuit 1 in FIG. 1 in the point that a delay circuit 80 is provided between the control circuit 30 and the oscillation circuit 20. The delay circuit 80 delays the enable signal OSCEN which has been output from the control circuit 30 and supplies a delayed enable signal DOSCEN to the oscillation circuit 20. Thereby, a delay occurs in the on-off control (that is, the intermittent operation of the oscillation circuit 20) of the output from the oscillation circuit 20. Further, the delay amount of the delay circuit 80 is cyclically fluctuated within the predetermined fluctuation range so as to reduce the EMI noise generated corresponding to the frequency of the intermittent operation of the oscillation circuit 20.

Describing in more detail, the delay circuit 80 includes a counter 82 which counts the number of pulses of the enable signal OSCEN which has been output from the control circuit 30, a variable delay unit 81 the delay amount of which is changed in accordance with the output COUNTOUT from the counter 82 and so forth. It is supposed that the number of counts of the counter 82 is cyclically reset. Since the configurations of other parts in FIG. 16 are the same as those in FIG. 1, the same reference numerals are assigned to the same or corresponding parts and repetitive description thereon is omitted.

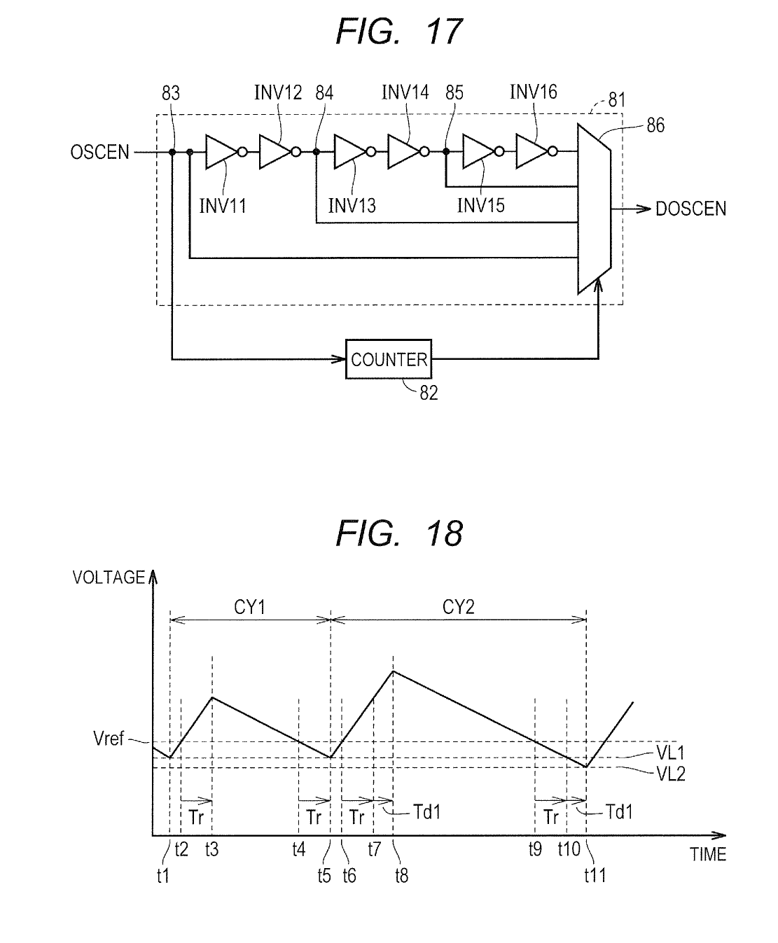

FIG. 17 is a circuit diagram illustrating a more detailed configurational example of the variable delay unit 81 in FIG. 16. Referring to FIG. 16 and FIG. 17, the variable delay unit 81 includes a delay unit configured by series-coupled inverters INV11 to INV16, a selector 86 and so forth. The selector 86 selects one of a group of nodes 83, 84 and 85 configured by the node 83 and the plurality of coupling nodes 84 and 85 of the inverters INV11 to INV16 in accordance with an output (the number of counts) from the counter 82 and supplies a signal which passes through the selected node to the oscillation circuit 20 as the delayed enable signal DOSCEN. Thereby, it becomes possible to change the delay amount of the variable delay unit 81 in accordance with the number of counts of the counter 82.

FIG. 18 is a diagram illustrating one example of a waveform of a divided voltage of the output voltage VOUT of the charge pump 10 in FIG. 16. In the example in FIG. 18, it is supposed that a load of a constant consumption current is coupled to the charge pump 10. It is also supposed that the delay amount of the delay circuit 80 is almost “0” from the time t1 to a time t5 and the delay amount of the delay circuit 80 is set to Td1 from the time t5 to a time t11.

Referring to FIG. 16 and FIG. 18, at the time t1, the oscillation circuit 20 is switched to an operative state and the output voltage of the charge pump 10 begins to increase. At the time t2, the divided voltage of the output voltage VOUT of the charge pump 10 exceeds the reference voltage Vref. However, since there is a delay in reaction of the control circuit 30, the oscillation circuit 20 is switched to a stop state at the time t3 that a reaction time Tr of the control circuit 30 has elapsed from the time t2.

At the next time t4, the divided voltage of the output voltage VOUT of the charge pump 10 is reduced to not more than the reference voltage Vref. Consequently, the oscillation circuit 20 is switched to the operative state at the time t5 that the reaction time Tr of the control circuit 30 has elapsed from the time t4.

When the load which is constant in consumption current is coupled to the charge pump 10 in this way, the oscillation circuit 20 repeats on-off operation at an intermittent frequency corresponding to a cycle CY1 and therefore the EMI noise may be generated corresponding to the intermittent frequency. Accordingly, timings at which the oscillation circuit 20 starts and stops the operation are more delayed by the delay circuit 80 and the delay time Td1 of the delay circuit 80 is fluctuated.

Specifically, at the time t5, the oscillation circuit 20 is switched to the operative state and the output voltage of the charge pump 10 beings to increase. At the time t6, the divided voltage of the output voltage VOUT of the charge pump 10 exceeds the reference voltage Vref. Consequently, the oscillation circuit 20 is switched to the stop state at a time t8 that the reaction time Tr of the control circuit 30 and the delay time Td1 of the delay circuit 80 have elapsed from the time t6.

At the next time t9, the divided voltage of the output voltage VOUT of the charge pump 10 is reduced to not more than the reference voltage Vref. Consequently, the oscillation circuit 20 is switched to the operative state at the time t11 that the reaction time Tr of the control circuit 30 and the delay time Td1 of the delay circuit 80 have elapsed from the time t9.

It is possible to extend a cycle CY2 that the oscillation circuit 20 repeats on/off operation as mentioned above by a time corresponding to the delay time Td1 of the delay circuit 80. Then, it is possible to reduce the EMI noise caused by the intermittent operation of the oscillation circuit 20 by fluctuating the delay time Td1. Further, the above-mentioned method has such a merit that it is possible to optionally set the delay time Td1 not depending on the cycle of the clock signal PUMPCLK.

### Fifth Embodiment

In the fourth embodiment, when the delay time Td1 of the delay circuit 80 has been fluctuated, a lower limit value of the output voltage VOUT of the charge pump 10 may be fluctuated. Specifically, as illustrated in FIG. 18, although in the first cycle CY1, the lower limit value of the divided voltage of the output voltage VOUT is maintained at a voltage VL1, in a second cycle CY2, the lower limit value of the divided voltage of the output voltage VOUT is lowered to a voltage VL2. The fourth charge pump type booster circuit 4 which will be described in the fifth embodiment is configured to improve the fluctuation in lower limit value. It is possible to combine the fifth embodiment with any of the first to third embodiments.

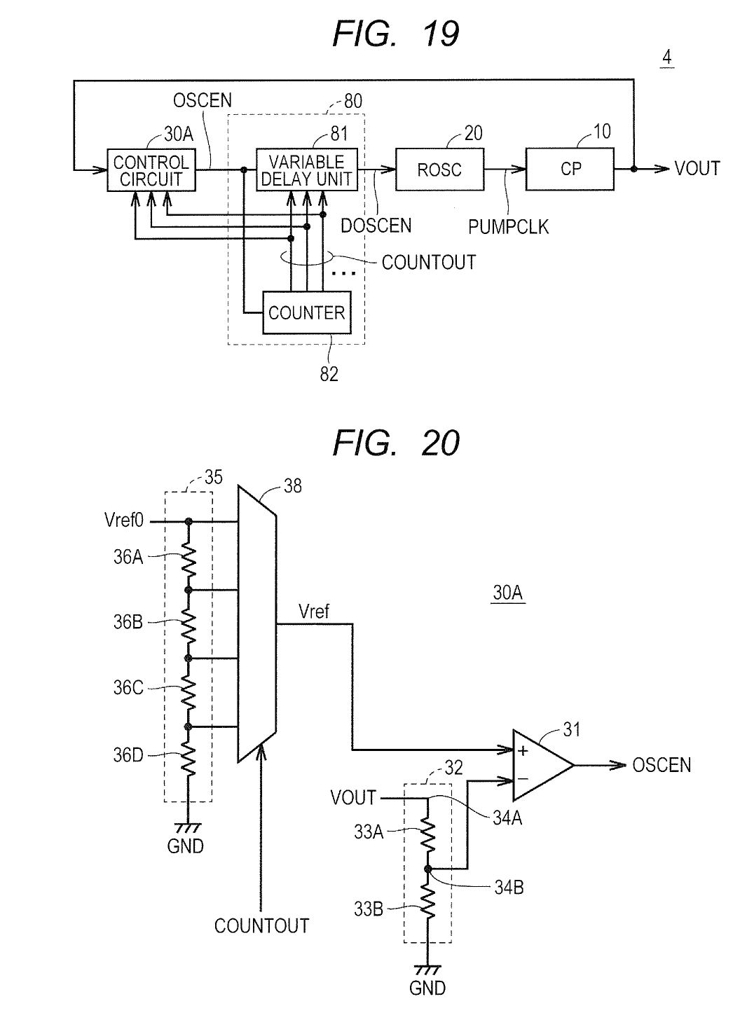

FIG. 19 is a block diagram illustrating a configurational example of the fourth charge pump type booster circuit 4. The booster circuit 4 in FIG. 19 is different from the booster circuit 3 in FIG. 16 in the point that a detection level of the output voltage VOUT of the charge pump 10 is changed in accordance with the number of counts of the counter 82. Specifically, the configuration of the control circuit 30A is different from that of the control circuit 30 in FIG. 16.

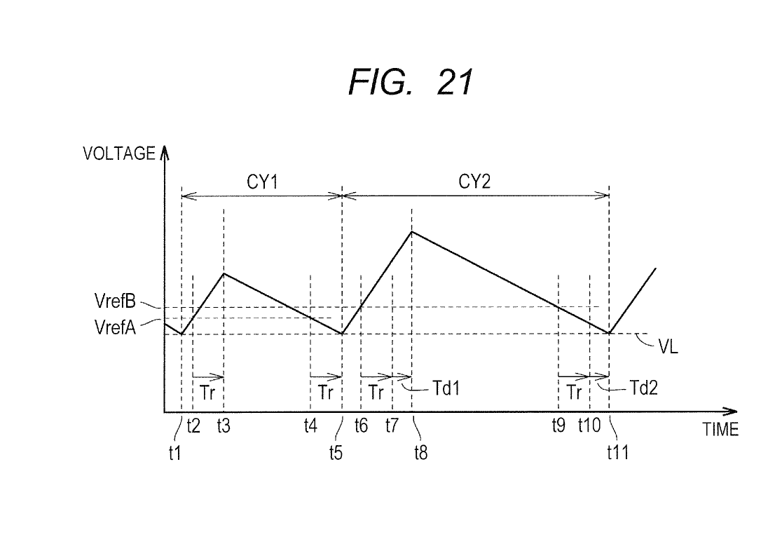

FIG. 20 is a circuit diagram illustrating a more detailed configurational example of the control circuit 30A in FIG. 19. The control circuit 30A in FIG. 20 is different from the control circuit 30 in FIG. 1 and FIG. 16 in the point that a voltage division circuit 35 and a selector 38 are additionally included. The voltage division circuit 35 divides a reference voltage Vref0 which serves as a basic voltage into divided voltages by a plurality of series-coupled resistance elements 36A to 36D. The selector 38 selects one of the plurality of divided voltages generated by the voltage division circuit 35 and the reference voltage Vref0 which serves as the basic voltage and outputs the selected voltage to the comparator 31 as the reference voltage Vref on the basis of the output COUNTOUT of the counter 82. Thereby, it is possible to change the reference voltage Vref in accordance with the number of counts of the counter 82.

FIG. 21 is a diagram illustrating one example of a waveform of the output voltage of the charge pump 10 in FIG. 19. The waveform chart in FIG. 21 corresponds to the waveform chart in FIG. 18.

As illustrated in FIG. 21, a voltage VrefA is set as the reference voltage in the first cycle CY1. Since, in the second cycle CY2, the reaction of the oscillation circuit 20 is delayed by the amount of the delay time Td1 by the delay circuit 80, the reference voltage is changed to a voltage VrefB having a higher value. Thereby, it is possible to maintain the lower limit value of the output voltage VOUT of the charge pump 10 almost at the same voltage level. In the example in FIG. 21, the lower limit value of the divided voltage of the output voltage VOUT is maintained constant at a value VL. The reference voltage Vref to be compared with the divided voltage of the output voltage of the charge pump 10 is changed to the voltage of a higher value as the delay time of the delay circuit 80 is extended in this way.

As described above, according to the fifth embodiment, such advantageous effects are obtained that it is possible to reduce the EMI noise caused by the intermittent operation of the oscillation circuit 20 and it is also possible to maintain the lower limit value of the divided voltage of the output voltage VOUT of the charge pump 10 constant.

### Altered Example of Fourth Embodiment

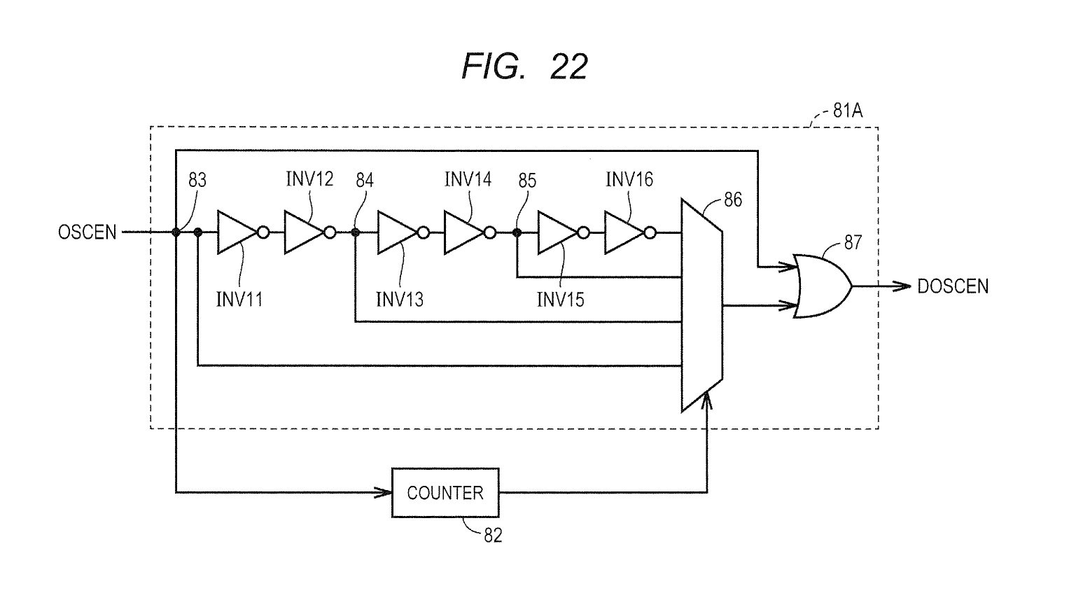

FIG. 22 is a circuit diagram illustrating the altered example 81A of the variable delay unit 81 in FIG. 17. The variable delay unit 81A in FIG. 22 is configured to delay a timing for level change only when the enable signal OSCEN output from the control circuit 30 is changed from the H level to the L level (that is, only when the enable signal OSCEN is changed from the active state to the inactive state). Thereby, it is possible to fluctuate the delay time of the delay circuit 80 while maintaining the lower limit value of the divided voltage of the output voltage VOUT of the charge pump 10 constant.

Specifically, as illustrated in FIG. 22, the variable delay unit 81A is different from the variable delay unit 81 in FIG. 17 in the point that an OR gate 87 is additionally included. The OR gate 87 outputs a logical sum of the output signal from the selector 86 and the enable signal OSCEN to the oscillation circuit 20 as the delayed enable signal DOSCEN. Thereby, when the enable signal OSCEN is changed from the L level to the H level (that is, when the enable signal OSCEN is changed from the inactive state to the active state), also the delayed enable signal DOSCEN is changed from the L level to the H level with almost no generation of the delay time.

### <Example of Semiconductor Device>

FIG. 23 is a block diagram illustrating one example of a semiconductor device which has the charge pump type booster circuit built-in. The semiconductor device in FIG. 23 is a micro-computer which has a flash memory built-in. The boosted voltage generated by the charge pump type booster circuit is used when rewriting (programming (writing)) data in the flash memory and erasing (deleting)) data.

Specifically, referring to FIG. 23, a semiconductor device 300 includes a central processing unit (CPU) 301, a RAM (Random Access Memory) 302, a ROM (Read Only Memory) 303, a flash memory 310, a bus 308 through which data and addresses are transferred, a system controller 304, a main clock circuit 306, a main power supply circuit 307, other peripheral circuits 305 and so forth.

The central processing unit 301 sequentially executes programs stored in the flash memory 310 and thereby controls the operation of the entire semiconductor device 300. The system controller 304 controls the operation of the entire of a data processor. The main clock circuit 306 generates an operation clock for the semiconductor device 300. The main power supply circuit 307 steps down the external power supply voltage VCC and then generates and supplies the internal operating voltage VDD and so forth to the central processing unit 301 and so forth.

The flash memory 310 includes a flash memory array 314, an interface circuit 311, a sensing amplifier 312, a Y-decoder 313, an X-decoder 315, a booster circuit 317, a sequencer 316 and so forth.

In the flash memory array 314, a plurality of flash memory cells are arranged in a matrix. The interface circuit 311 receives the address and write data (program data) of the flash memory array 314 from the central processing unit 301 via the bus 308 and outputs read-out data from the flash memory array 314 to the central processing unit 301 via the bus 308. The sensing amplifier 312 compares a signal read out of the flash memory array 314 with a reference signal and thereby outputs the read-out data. The Y-decoder 313 decodes a column address and selects a column to be read, programmed or erased in the flash memory array 314. The X-decoder 315 decodes a row address and selects a row to be read, programmed or erased in the flash memory array 314.

The booster circuit 317 generates the boosted voltage VOUT used when programming data and erasing data in the memory cells of the flash memory array 314. The booster circuit 317 includes any of the booster circuits 1 to 4 described in the first to the fifth embodiments plurally. Thereby, it is possible to reduce the EMI noise. The operation of the booster circuit 317 is controlled by the sequencer 316 on the basis of a command from the central processing unit 301.

In the foregoing, the invention which has been made by the inventors and others of the present invention has been specifically described on the basis of the preferred embodiments. However, it goes without saying that the present invention is not limited to the above-mentioned embodiments and may be altered and modified in a variety of ways within the scope not deviating from the gist of the present invention.

What is claimed is:

1. A semiconductor device, comprising:
a first charge pump which operates in accordance with a first clock signal and thereby generates a boosted voltage of a polarity which is the same as or reverse to the polarity of an input voltage; and
an oscillation circuit which generates and outputs the first clock signal,
wherein the oscillation circuit cyclically fluctuates a frequency of the first clock signal within a predetermined fluctuation range.

2. The semiconductor device according to claim 1,
wherein the oscillation circuit includes a ring oscillator configured by combing together a plurality of delay elements in a ring-shape, and
wherein a delay amount of at least one of the delay elements is cyclically fluctuated within the predetermined fluctuation range.

3. The semiconductor device according to claim 2,
wherein the oscillation circuit further includes a power supply circuit which supplies an operating voltage for at least one of the delay elements, and
wherein the power supply circuit cyclically fluctuates the operating voltage within the predetermined fluctuation range.

4. The semiconductor device according to claim 3,
wherein the power supply circuit includes
a triangular wave generator which generates a triangular wave the voltage of which cyclically fluctuates between a first voltage and a second voltage, and
a voltage step-down converter which generates the operating voltage by stepping down an applied power supply voltage in accordance with a voltage level of the triangular wave.

5. The semiconductor device according to claim 2,
wherein the oscillation circuit further includes a counter which counts a number of pulses of the first clock signal, and
wherein at least one of the delay elements is configured such that the delay amount is changed in accordance with a number of counts of the counter.

6. The semiconductor device according to claim 5,
wherein the oscillation circuit includes
a capacitance element coupled between an output node of the at least one delay element and a reference potential node to which a power supply voltage or a ground voltage has been applied, and
a variable current source inserted into a power supply wire or a grounding wire of the at least one delay element, and
wherein a current amount of the variable current source is changed in accordance with the number of counts of the counter.

7. The semiconductor device according to claim 1, further comprising:
a second charge pump which operates in accordance with a second clock signal generated by the oscillation circuit and thereby generates a boosted voltage of a polarity which is the same as or reverse to the polarity of the input voltage,
wherein the oscillation circuit cyclically fluctuates a frequency of the second clock signal within the predetermined fluctuation range, and
wherein the frequency of the first clock signal and the frequency of the second clock signal obtained at the same hour are different from each other.

8. The semiconductor device according to claim 7,
wherein the oscillation circuit includes a ring oscillator configured by combing together a plurality of delay elements in a ring-shape,
wherein a delay amount of at least one of the delay elements is cyclically fluctuated within the predetermined fluctuation range, and
wherein the first and second clock signals are output signals of mutually different delay elements in the delay elements.

9. The semiconductor device according to claim 7,
wherein the oscillation circuit includes
a first oscillation circuit which generates the first clock signal, and
a second oscillation circuit which generates the second clock signal,
wherein each of the first and second oscillation circuits includes a ring oscillator configured by combing together a plurality of delay elements in a ring-shape, and
wherein a number of the delay elements of the first oscillation circuit and a number of the delay elements of the second oscillation circuit are different from each other.

10. The semiconductor device according to claim 1, further comprising:
a control circuit which detects a boosted voltage output from the first charge pump, compares a divided voltage of the boosted voltage so detected with a reference voltage and outputs a control signal for performing on/off control on an output from the oscillation circuit on the basis of a result of comparison; and
a delay circuit which is provided between the control circuit and the oscillation circuit and delays the control signal,
wherein the delay circuit cyclically fluctuates a delay amount of the control signal within the predetermined fluctuation range.

11. The semiconductor device according to claim 10,
wherein the delay circuit includes a counter which counts a number of pulses of the control signal and changes the delay amount of the control signal in accordance with a number of counts of the counter.

12. The semiconductor device according to claim 11,
wherein the control circuit changes the reference voltage such that the more the delay amount of the control signal is increased, the more an absolute value of the reference voltage is increased, on the basis of the number of counts of the counter.

13. The semiconductor device according to claim 10,
wherein the oscillation circuit is configured so as to perform an oscillating operation when the received control signal is in an active state and to stop the oscillating operation when the received control signal is in an inactive state, and
wherein the delay circuit cyclically fluctuates a timing at which the state of the control signal is changed from the active state to the inactive state within the predetermined fluctuation range and does not fluctuate a timing at which the state of the control signal is changed from the inactive state to the active state.

14. A semiconductor device, comprising:
a charge pump which operates in accordance with a clock signal and thereby generates a boosted voltage of a polarity which is the same as or reverse to the polarity of an input voltage;
an oscillation circuit which generates and outputs the clock signal;
a control circuit which detects the boosted voltage output from the charge pump, compares a divided voltage of the boosted voltage so detected with a reference voltage and outputs a control signal for performing on/off control on an output from the oscillation circuit on the basis of a result of comparison; and
a delay circuit which is provided between the control circuit and the oscillation circuit and delays the control signal,
wherein the delay circuit cyclically fluctuates a delay amount of the control signal within a predetermined fluctuation range.
